(19) United States
(12) Patent Application Publication
(10) Pub. No.: US 2025/0098374 A1
(43) Pub. Date: Mar. 20, 2025

(54) LIGHT EMITTING ELEMENT

(71) Applicant: NICHIA CORPORATION, Anan-shi (JP)

(72) Inventor: Akira FUJIOKA, Tokushima-shi (JP)

(73) Assignee: NICHIA CORPORATION, Anan-shi (JP)

(21) Appl. No.: 18/827,150

(22) Filed: Sep. 6, 2024

(30) Foreign Application Priority Data
Sep. 19, 2023 (JP) 2023-151627

(51) Int. Cl. H01L 33/46; H01L 25/075; H01L 33/22

(52) U.S. Cl. CPC H10H 20/841; H10H 20/82; H01L 25/0753

(57) ABSTRACT

A light emitting element includes: a semiconductor structure including: a first semiconductor layer that has: a first face that has a peripheral region, and a central region surrounded by the peripheral region in a plan view, wherein a surface roughness of the central region is higher than a surface roughness of the peripheral region, and a second face that opposes the first face and has a first region and a second region, an active layer disposed on the first region, and a second semiconductor layer disposed on the active layer; a first electrode disposed on the second region and electrically connected to the first semiconductor layer; a second electrode disposed on the second semiconductor layer and electrically connected to the second semiconductor layer; a first reflecting film disposed only on the peripheral region among the surfaces of the semiconductor structure; and a first protective film disposed on the central region.

### CROSS-REFERENCE TO RELATED APPLICATIONS

The present application claims priority under 35 U.S.C. § 119 to Japanese Patent Application No. 2023-151627, filed Sep. 19, 2023, the entire contents of which are hereby incorporated by reference.

### BACKGROUND

### 1. Technical Field

The present disclosure relates to a light emitting element.

### 2. Description of Related Art

For example, Japanese Patent Publication No. 2015-32809 discloses a light emitting element in which a first face of a semiconductor layer is formed as an uneven surface.

### SUMMARY

One object of certain embodiments of the present disclosure is to provide a light emitting element having a large brightness difference between the central region and the peripheral region of a primary light extraction face.

According to an embodiment of the present disclosure, a light emitting element includes: a semiconductor structure having a first semiconductor layer which has a first face and a second face that opposes the first face and has a first region and a second region, an active layer disposed on the first region, and a second semiconductor layer disposed on the active layer; a first electrode disposed on the second region and electrically connected to the first semiconductor layer; and a second electrode disposed on and electrically connected to the second semiconductor layer. The first face has a peripheral region and a central region that is surrounded by the peripheral region in a plan view and has higher surface roughness than that of the peripheral region. A first reflecting film is disposed only on the peripheral region among the surfaces of the semiconductor structure, and a first protective film having a higher light transmittance for the peak wavelength of the light emitted by the active layer than that of the first reflecting film is disposed on the central region.

According to certain embodiments of the present disclosure, a light emitting element having a large brightness difference between the central region and the peripheral region of a primary light extraction face can be provided.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic plan view of a light emitting element according to an embodiment of the present invention.

FIG. 2 is a schematic cross-sectional view taken along line II-II in FIG. 1.

FIG. 3A is a schematic cross-sectional view of a first reflecting film according to the embodiment.

FIG. 3B is a schematic cross-sectional view of a second reflecting film according to the embodiment.

FIG. 4 is a schematic cross-sectional view of a light emitting device according to an embodiment.

### DETAILED DESCRIPTION OF EMBODIMENT

### Embodiments

Certain embodiments of the present disclosure will be explained with reference to the accompanying drawings. The dimensions, materials, shapes, relative positions of the constituents in the embodiments described below are not intended to limit them to those described unless otherwise specifically noted, and are merely provided for explanation purposes. The sizes of and positional relationships between members shown in each drawing might be exaggerated for clarity of explanation. Moreover, in the description below, the same designations or reference numerals basically show the same members or those of similar quality, for which detailed explanation will be omitted as appropriate. An end face that shows a cut section might be used as a cross-sectional view.

In the description below, terms indicating specific directions or positions (e.g., “upper,” “on,” “lower,” “under,” and other terms including or related to these) may be used. These terms, however, are merely used in order to make the relative directions or positions in the drawings being referenced more easily understood. As long as the relationship between relative directions or positions indicated with the terms such as “upper,” “on,” “lower,” “under,” or the like is the same as those in a referenced drawing, the layout of the elements in other drawings or actual products outside of the present disclosure does not have to be the same as those shown in the referenced drawing. The positional relationship expressed with the term “on (or under)” in the present specification includes the case in which a member is in contact with another member, and the case in which a member is not in contact with, but positioned above (or under) another member.

Unless otherwise specifically noted, “covering” includes not only the case in which a member directly covers an object in contact with the object, but also the case in which a member indirectly covers an object without contacting the object.

Directions may be indicated in the drawings with X axis, Y axis, and Z axis. The X, Y, and Z axes are orthogonal to one another. In the present specification, for example, the directions along the Z, X, and Y axes will be referred to as first direction Z, second direction X, and third direction Y, respectively.

### Light Emitting Element

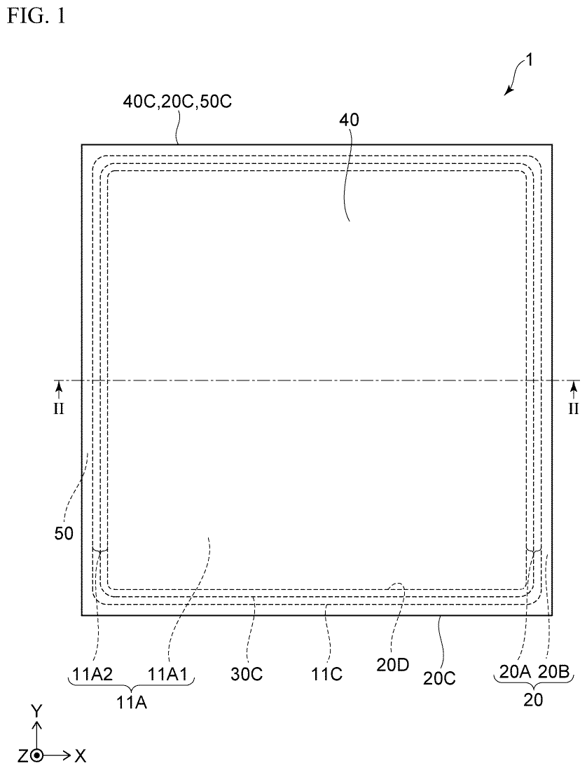

As shown in FIG. 1, a light emitting element 1 according to an embodiment is, for

example, quadrangular in a plan view, and has two sides extending in the second direction X and two sides extending in the third direction Y. The length of a side of the light emitting element 1 in a plan view is, for example, in a range of 30 μm to 1000 μm.

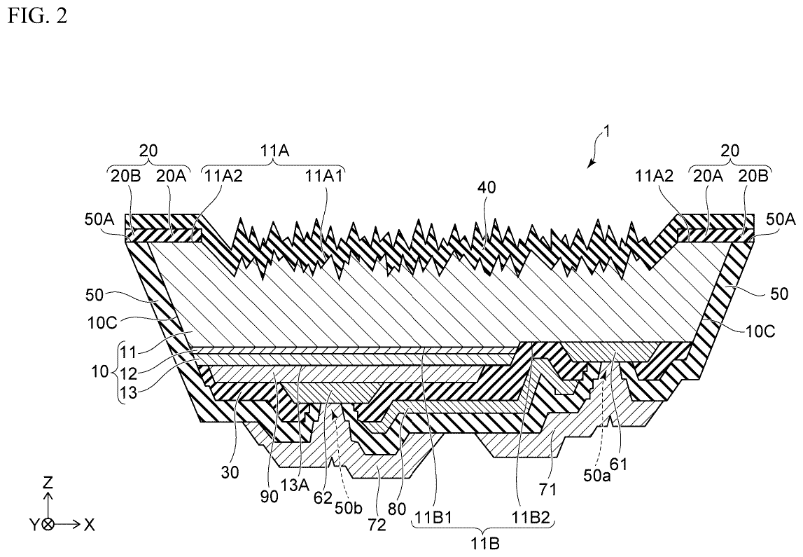

As shown in FIG. 2, the light emitting element 1 includes a semiconductor structure 10, a first electrode 61, a second electrode 62, a first reflecting film 20, and a first protective film 40. Each constituent will be explained in detail below.

### Semiconductor Structure

A semiconductor structure 10 is made of a nitride semiconductor. In the present specification, “nitride semiconductors” include, for example, semiconductors of any composition obtained by varying the composition ratio x and y within their ranges in the chemical formula of InₓAl_{y}Ga_{1-x-y}N (0≤x≤1, 0≤y≤1, x+y≤1). The “nitride semiconductors” also include those represented by the chemical formula above that further includes group V elements other than N (nitrogen), and various elements added to control the physical properties such as conductivity type.

The semiconductor structure 10 has a first semiconductor layer 11, an active layer 12, and a second semiconductor layer 13. The first semiconductor layer 11 has a semiconductor layer containing an n-type impurity. The second semiconductor layer 13 has a semiconductor layer containing a p-type impurity. The active layer 12 is an emission layer that emits light, and has, for example, a MQW (multiple quantum well) structure that includes multiple barrier layers and multiple well layers. The active layer 12 emits light having a peak wavelength in a range of 210 nm to 580 nm, for example.

The first semiconductor layer 11 has a first face 11A and a second face 11B positioned opposite the first face 11A in the first direction Z.

The first face 11A is a face of the light emitting element 1 from which light is extracted primarily. The first face 11A has a central region 11A1 and a peripheral region 11A2. As shown in FIG. 1, in the plan view, the central region 11A1 is surrounded by the peripheral region 11A2. In the plan view, the border between the central region 11A1 and the peripheral region 11A2 coincides with the inner perimeter 20D of the first reflecting film 20 described below. In the plan view, the area of the central region 11A1 is larger than the area of the peripheral region 11A2. The peripheral region 11A2 is a region that is within 10 μm, preferably within 5 μm from the outer perimeter of the first face 11A.

The light emitted by the active layer 12 can be extracted from the semiconductor structure 10 from the central region 11A1. The central region 11A1 is roughened to be rougher than the surface roughness of the peripheral region 11A2. This can improve the efficiency in extracting light from the central region 11A1. Chipping might occur around the outer edges of the semiconductor structure 10. In this embodiment, the surface of the peripheral region 11A2 being less rough than the central region 11A1 can enhance the strength of the first semiconductor layer 11 near the perimeter 11C of the first face 11A to thereby reduce the occurrence of chipping in the first semiconductor layer 11 as compared to the case in which the surface roughness of the peripheral region 11A2 is equal to or rougher than the surface roughness of the central region 11A1. In the present specification, surface roughness is, for example, an average surface roughness Ra. The average surface roughness Ra of the central region 11A1 is, for example, 100 nm to 400 nm. The average surface roughness Ra of the peripheral region 11A2 is, for example, 1 nm to 10 nm. Here, the surface roughness of the central region 11A1 and the peripheral region 11A2 can be measured by using a laser microscope, atomic force microscope, or the like.

The central region 11A1 can be roughened by dry etching or wet etching. During roughening of the central region 11A1, the peripheral region 11A2 of the first face 11A is masked and protected.

The second face 11B has a first region 11B1 and a second region 11B2. In a plan view, the area of the first region 11B1 is larger than the area of the second region 11B2. The active layer 12 is disposed on the first region 11B1 in the second face 11B. In FIG. 2, the active layer 12 is shown under the first region 11B1, and the active layer 12 being placed on the surface of the first region 11B1 in this manner is described as “the active layer 12 is disposed on the first region 11B1 in the second face 11B.”

### First Electrode and Second Electrode

A first electrode 61 is disposed on the second region 11B2 and electrically connected to the first semiconductor layer 11. A second electrode 62 is disposed on the second semiconductor layer 13 and electrically connected to the second semiconductor layer 13. The first electrode 61 and the second electrode 62 can be, for example, a single metal layer including Ti, Rh, Au, Pt, Al, Ag, or Ru, or a stack structure that includes at least two of these metal layers.

### First Reflecting Film

A first reflecting film 20 is disposed only on the peripheral region 11A2 of the first face 11A among the surfaces of the semiconductor structure 10. The surfaces of the semiconductor structure 10 include the first face 11A of the first semiconductor layer 11, the upper face 13A of the second semiconductor layer 13, the second region 11B2 of the second face 11B of the first semiconductor layer 11, the lateral faces of the first semiconductor layer 11, the lateral faces of the active layer 12, and the lateral faces of the second semiconductor layer 13. The upper face 13A of the second semiconductor layer 13 is the face of the second semiconductor layer 13 that is not on the active layer 12 side. The first reflecting film 20 is not disposed on the central region 11A1 of the first face 11A, the upper face 13A of the second semiconductor layer 13, the second region 11B2 of the second face 11B, the lateral faces of the first semiconductor layer 11, the lateral faces of the active layer 12, and the lateral faces of the second semiconductor layer 13. The regions other than the peripheral region 11A2 on which the first reflecting film 20 is disposed are, for example, those located on the second protective film 50 described below.

The first reflecting film 20 reflects the light emitted by the active layer 12. The light reflectance of the first reflecting film 20 with respect to the peak wavelength of the light emitted by the active layer 20 is, for example, 40% or higher, preferably 60% or higher. For the first reflecting film 20, for example, a dielectric multilayer film can be used. Materials for the dielectric multilayer film will be discussed below. For the first reflecting film 20, for example, a metal film including aluminum or silver may be used. Using a dielectric multilayer film for the first reflecting film 20 can reduce the absorption of light by the first reflecting film 20 as compared to a metal layer.

### First Protective Film

A first protective film 40 is disposed on the central region 11A1 of the first face 11A. The light transmittance of the first protective film 40 with respect to the peak wavelength of the light emitted by the active layer 12 is higher than the light transmittance of the first reflecting film 20 with respect to the peak wavelength of the light emitted by the active layer 12. The light transmittance of the first protective film 40 with respect to the peak wavelength of the light emitted by the active layer 12 is, for example, 70% or higher, preferably 90% or higher. For the first protective film 40, for example, SiO₂ can be used. The light emitted by the active layer 12 is extracted primarily via the first protective film 40. The thickness of the first protective film 40 is, for example, in a range of 0.1 μm to 1 μm. Here, the thickness of the first protective film 40 means the maximum thickness of the first protective film 40 in the first direction Z.

Not roughening the peripheral region 11A2 can facilitate total internal reflection of the light from the active layer 12 at the interface between the peripheral region 11A2 and the first reflecting film 20. Disposing a first reflecting film 20 on the peripheral region 11A2 allows the first reflecting film 20 to reflect the light emitted by the active layer 12. This can increase the brightness gap in the first face 11A between the central region 11A1 and the peripheral region 11A2 located outward from the central region 11A1. In other words, when the light emitting element 1 is observed from the first face 11A side, the peripheral region 11A2 can be made less bright than the central region 11A1. As a result, when the light emitting element 1 is observed from the first face 11A side, the brightness difference between the light emitting element 1 and the vicinity of the light emitting element 1 can be increased.

The light emitted by the active layer 12 can also be extracted from the lateral faces 10C of the semiconductor structure 10. The lateral faces 10C of the semiconductor structure 10 connect the first face 11A of the first semiconductor layer 11 and the upper face 13A of the second semiconductor layer 13, and connect the first face 11A and the second region 11B2 of the second face 11B.

No reflecting film, such as a first reflecting film 20, is disposed on the lateral faces 10C of the semiconductor structure 10. If a reflecting film is disposed on the lateral faces 10C, the light from the active layer 12 would be reflected by the reflecting film on the lateral faces 10C to be readily absorbed by the semiconductor structure 10. This could consequently facilitate the reduction of the light extraction efficiency of the light emitting element 1. Accordingly, not disposing a reflecting film on the lateral faces 10C of the semiconductor structure 10 can increase the light extraction efficiency of the light emitting element 1. The percentage of the light extracted from the lateral faces 10C increases as the plan size of the light emitting element 1 decreases. Accordingly, the structure that excludes a reflecting film on the lateral faces 10C has a great effect when the length of each side of the first face 11A in a plan view is relatively small. For example, the length of a side of the first face 11A in a plan view being 100 μm or less produces a great effect, and the length being 60 μm or less produces a greater effect.

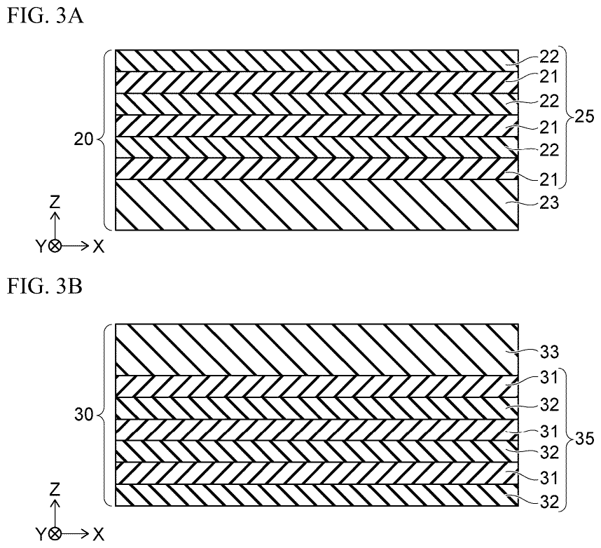

The first reflecting film 20 can have, for example, the first dielectric multilayer film 25 shown in FIG. 3A. The first dielectric multilayer film 25 can include multiple first films 21 and multiple second films 22. The first films 21 and the second films 22 are alternately stacked in the first direction Z. For example, the first films 21 are Nb₂O₅ and the second films 22 are SiO₂.

For the first dielectric multilayer film 25, two to six pairs of a first film 21 having a thickness in a range of 10 nm to 100 nm and a second film 22 having a thickness in a range of 10 nm to 100 nm are preferably formed. Setting the thickness of each film and the number of pairs for the first dielectric multilayer film 25 as described above can achieve a high reflectance. Furthermore, all of the first films 21 preferably have the same thickness. All of the second films 22 preferably have the same thickness.

The first reflecting film 20 may further have a fifth film 23. The fifth film 23 is disposed on the peripheral region 11A2 of the first face 11A, and the first films 21 and the second films 22 are alternately stacked on the fifth film 23. For example, The fifth film 23 is a SiO₂ film. The thickness of the fifth film 23 is larger than the thickness of each first film 21 and second film 22. The thickness of the fifth film 23 is, for example, 100 nm to 500 nm. Such a thick fifth film 23 can increase the effectiveness of total internal reflection at the interface between the fifth film 23 and the peripheral region 11A2 of the first face 11A.

For example, for the first reflecting film 20, a SiO₂ fifth film 23 of 100 nm in thickness can be formed, followed by forming thereon three pairs of an Nb₂O₅ first film 21 of 57.2 nm in thickness and a SiO₂ second film 22 of 91.3 nm in thickness.

In FIG. 1, the perimeter 20C of the first reflecting film 20 in the plan view is indicated by the solid line, and the perimeter 11C of the first face 11A is indicated by the outermost broken line. The perimeter 11C of the first face 11A constitutes the outermost edge of the semiconductor structure 10 in the plan view. The first reflecting film 20 can have a first portion 20A that overlaps the peripheral region 11A2 and a second portion 20B that extends from the first portion 20A outward from the semiconductor structure 10 in the plan view. In the plan view, the second portion 20B of the first reflecting film 20 extends out from the perimeter 11C of the first face 11A. In this embodiment, the second portion 20B is disposed in contact with the second protective film 50 described below. This can facilitate the reflection of the light that exits the lateral faces 10C of the semiconductor structure 10 by the second portion 20B of the first reflecting film 20, thereby increasing the difference in the brightness of light between the central region 11A1 and the region outward from the central region 11A1.

In the plan view, the area of the second portion 20B is preferably smaller than the area of the first portion 20A. This makes the first reflecting film 20 less prone to chipping. The extension length of the second portion 20B from the peripheral region 11A2 in the second direction X is preferably smaller than the length of the first portion 20A in the second direction X. The extension length of the second portion 20B from the peripheral region 11A2 in the third direction Y is preferably smaller than the length of the first portion 20A in the third direction Y. The extension lengths of the second portion 20B from the peripheral region 11A2 in the second direction X and the third direction Y are preferably 1 μm or less.

As shown in FIG. 2, the first protective film 40 can be disposed on the first reflecting film 20 continuously over the central region 11A1 and the peripheral region 11A2. The first protective film 40 covers the central region 11A1 over the protrusions of the central region 11A1, also producing protrusions in the upper face of the first protective film 40. The surface of the first protective film 40 on the central region 11A1 is rougher than the surface of the first protective film 40 on the first reflecting film 20. This can increase the extraction efficiency of the light that became incident on the first protective film 40 from the central region 11A1 extracted from the first protective film 40. The surface of the first protective film 40 on the first reflecting film 20 being less rough than the surface of the first protective film 40 on the central region 11A1 can facilitate total internal reflection of the light passing through the first reflecting film 20 at the interface between the first protective film 40 on the first reflecting film 20 and an air or resin layer, for example.

### Second Protective Film

The light emitting element 1 may further include a second protective film 50. The second protective film 50 is disposed on the lateral faces 10C of the semiconductor structure 10, covering the lateral faces 10C of the semiconductor structure 10. The light transmittance of the second protective film 50 with respect to the peak wavelength of the light from the active layer 12 is higher than the light transmittance of the first reflecting film 20 with respect to the peak wavelength of the light from the active layer 12. The light transmittance of the second protective film 50 with respect to the peak wavelength of the light from the active layer 12 is, for example 70% or higher, preferably 90% or higher. For the second protective film 50, for example, a SiO₂ film can be used. The thickness of the second protective film 50 is, for example, in a range of 0.2 μm to 2 μm.

As shown in FIG. 1, the perimeter 50C of the second protective film 50 in the plan view coincides with the perimeter 20C of the first reflecting film 20. Alternatively, the perimeter 50C is positioned inward of the perimeter 20C of the first reflecting film 20 in the plan view. In other words, the upper end face 50A of the second protective film 50 is covered by the first reflecting film 20. The first reflecting film 20 is allowed to reflect the light that exited the lateral faces 10 of the semiconductor structure 10, became incident on the second protective film 50, and is advancing in the second protective film 50 towards the upper end face 50A. This can increase the difference in the brightness of light between the central region 11A1 and the region outward from the central region 11A1.

In the plan view, the perimeter 40C of the first protective film 40 coincides with the perimeter 50C of the second protective film 50 and the perimeter 20C of the first reflecting film 20.

### Second Reflecting Film

The light emitting element 1 may further include a second reflecting film 30. The second reflecting film 30 covers at least the upper face 13A side of the second semiconductor layer 13. The second reflecting film 30 reflects the light emitted by the active layer 12. The reflectance of the second reflecting film 30 for the peak wavelength of the light emitted by the active layer 12 is, for example 40% or higher, preferably 60% or higher. The light travelling from the active layer 13 towards the upper face 13A of the second semiconductor layer 13 can be reflected by the second reflecting film 30 towards the central region 11A1 of the first face 11A. This can increase the efficiency in extracting light from the central region 11A1.

The second reflecting film 30 can cover substantially the entire face positioned opposite the first face 11A in the semiconductor structure 10. This can increase the amount of light reflected towards the central region 11A1, thereby further increasing the efficiency in extracting light from the central region 11A1.

The second reflecting film 30 preferably overlaps the first reflecting film 20 in a plan view. As shown in FIG. 1, in the plan view, the perimeter 30C of the second reflecting film 30 is positioned between the inner perimeter 20D of the first reflecting film 20 and the outer perimeter 20C of the first reflecting film 20. Having the second reflecting film 30 overlap the first reflecting film 20 in the plan view allows the second reflecting film 30 to reflect the light that was reflected by the second reflecting film 30 downwards towards the central region 11A1, thereby improving the efficiency in extracting light from the central region 11A1. In the plan view, the overlapping area of the first reflecting film 20 and the second reflecting film 30 is preferably 40% of the first reflecting film 20 or larger.

The second reflecting film 30 can have, for example, the second dielectric multilayer film 35 shown in FIG. 3B. The second dielectric multilayer film 35 can have multiple third films 31 and multiple fourth films 32. The third films 31 and the fourth films 32 are alternately stacked in the first direction Z. For example, the third films 31 are Nb₂O₅ and the fourth films 32 are SiO₂.

For the second dielectric multilayer film 35, two to six pairs of a third film 31 having a thickness in a range of 10 nm to 100 nm and a fourth film 32 having a thickness in a range of 10 nm to 100 nm are preferably formed. Setting the thicknesses and the number of pairs of the films as described above for the second dielectric multilayer film 35 can achieve a good light reflectance. The third films 31 preferably have the same thickness. The fourth films 32 preferably have the same thickness.

The second reflecting film 30 may further include a sixth film 33. The sixth film 33 is disposed closer to the semiconductor structure 10 than the second dielectric multilayer film 35 is, and the third films 31 and the fourth films 32 are alternately stacked on the sixth film 33. For example, the sixth film 33 is a SiO₂ film. The thickness of the sixth film 33 is larger than the thicknesses of each third film 31 and each fourth film 32. The thickness of the sixth film 33 is, for example, in a range of 100 nm to 500 nm. Such a thick sixth film 33 can easily increase the effect of total internal reflection at the interface between the sixth film 33 and the semiconductor structure 10.

For example, for the second reflecting film 30, a SiO₂ sixth film 33 of 300 nm in thickness can be formed, followed by forming three pairs of an Nb₂O₅ third film 31 of 52 nm in thickness and a SiO₂ fourth film 32 of 83 nm in thickness.

### Third Reflecting Film

The light emitting element 1 may further include a third reflecting film 80 disposed on the second reflecting film 30. The third reflecting film 80 reflects the light emitted by the active layer 12. The light extraction efficiency can be increased by allowing the third reflecting film 80 to reflect the light that transmitted through the second reflecting film 30 towards the central region 11A1. The third reflecting film 80 is, for example, a metal film. The third reflecting film 80 is, for example, Al, Ti, or a stack structure including these.

### Light Transmissive Conducting Film

The light emitting element 1 may further include a light transmissive conducting film 90. The light transmissive conducting film 90 is disposed on the upper face 13A of the second semiconductor layer 13. A second electrode 62 is disposed on the light transmissive conducting film 90. The second semiconductor layer 13 is electrically connected to the second electrode 62 via the light transmissive conducting film 90. The light transmissive conducting film 90 has the function of diffusing the electric current supplied through the second electrode 62 in the second semiconductor layer 13 in the in-plane direction. For the materials for the light transmissive conducting film 90, for example, ITO (indium tin oxide), IZO (indium zinc oxide), ZnO, In₂O₃, or the like can be used. The thickness of the light transmissive conducting film 90 is, for example, in a range of 0.03 μm to 0.3 μm.

### First Conducting Member and Second Conducting Member

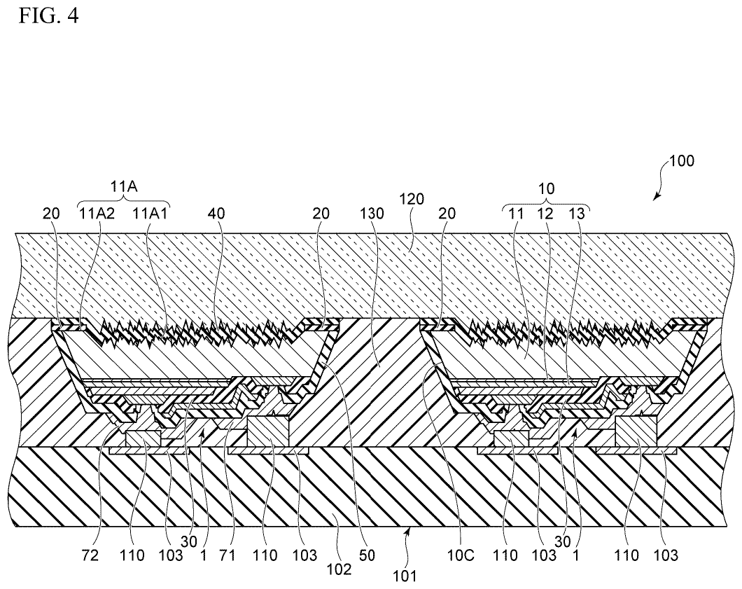

The light emitting element 1 may further include a first conducting member 71 and a second conducting member 72. The first conducting member 71 is electrically connected to a first electrode 61. As described below with reference to FIG. 4, the first conducting member 71 and the second conducting member 72 are electrically connected to a wiring substrate 101 via a bonding material 110, such as solder or bumps, for example. The second conducting member 72 is electrically connected to a second electrode 62. The first conducting member 71 and the second conducting member 72 are, for example, Ti, Rh, Au, Pt, Ru, Al, or a stack structure that includes any two of these.

The second protective film 50 can be disposed on the side of the semiconductor structure 10 that opposes the first face 11A so as to cover the second reflecting film 30, the third reflecting film 80, the first electrode 61, and the second electrode 62. The first conducting member 71 and the second conducting member 72 are disposed in contact with the second protective film 50. The first conducting member 71 and the second conducting member 72 are disposed apart from one another. The first conducting member 71 can be connected to the first electrode 61 at a first opening 50a created in the second protective film 50, and the second conducting member 72 can be connected to the second electrode 62 at a second opening 50b created in the second protective film 50.

### Light Emitting Device

A light emitting device 100 according to an embodiment will be explained with reference to FIG. 4.

The light emitting device 100 includes a wiring substrate 101, any of the light emitting elements 1 described above that is disposed on the wiring substrate 101, and a wavelength conversion member 120 disposed on the light emitting element 1. For example, multiple light emitting elements 1 are disposed on the wiring substrate 101. FIG. 4 shows two light emitting elements 1, but three or more light emitting elements 1 may be disposed on the wiring substrate 101. Each light emitting element 1 is disposed on the wiring substrate 101 with the first conducting member 71 and the second conducting member 72 opposing the upper face of the wiring substrate 101.

The wiring substrate 101 has an insulation base 102 and a wiring part 103 disposed at least on the upper face of the insulation base 102. The first conducting member 71 and the second conducting member 72 of the light emitting element 1 are each bonded to and electrically connected to a wiring part 103 via a bonding material 110. For the bonding material 110, for example, Cu, Au, or the like can be used. The light emitting elements 1 can be individually ON-OFF controlled.

The wavelength conversion member 120 is disposed on the upper faces of the light emitting elements 1 and regions between adjacent light emitting elements 1 so as to straddle the light emitting elements 1 continuously. The wavelength conversion member 120 is in contact with the upper face of the first protective film 40 while filling the gaps between the protrusions of the upper face of the first protective film 40 on the central region 11A1 of the first face 11A. The wavelength conversion member 120 includes a base material made of a light transmissive material and a phosphor dispersed in the base material, for example. For the base material, for example, an epoxy resin, a silicone resin, a resin combining these, glass, or the like can be used. The color of the light after wavelength conversion by the phosphor is, for example, yellow. For a yellow emitting phosphor, one having a composition represented by Y₃Al₅O₁₂:Ce or (Y,Lu,Gd)₃(Al,Ga)₅O₁₂:Ce can be used. In the case of using a yellow emitting phosphor having such a composition, the peak wavelength of the light emitted by the active layer 12 is preferably 420 nm to 490 nm, for example.

In the case of disposing a wavelength conversion member 120 on the light emitting element 1, the thickness of the first reflecting film 20 is preferably larger than the thickness of the second reflecting film 30. This allows the first reflecting film 20 to readily reflect the wavelength converted light converted by the wavelength conversion member 120 having a longer wavelength than the light emitted by the active layer 12 towards the space above the light emitting element 1. This, as a result, can increase the brightness of the light emitting device 100. In the case of disposing a wavelength conversion member 120 on the light emitting element 1, for example, the thickness of the first reflecting film 20 is preferably in a range of 1.05 to 1.2 times the thickness of the second reflecting film 30. In the case in which the first reflecting film 20 has a first dielectric multilayer film 25 and the second reflecting film 30 has a second dielectric multilayer film 35, the thickness of each first film 21 is preferably larger than the thickness of each third film 31 and the thickness of each second film 22 is preferably larger than the thickness of each fourth film 32. This can increase the reflectance of the first reflecting film 20 for the peak wavelength of the wavelength converted light converted by the wavelength conversion member 120 while increasing the reflectance of the second reflecting film 30 for the peak wavelength of the light emitted by the active layer 12. The reflectance of the first reflecting film 20 for the peak wavelength of the wavelength converted light converted by the wavelength conversion member 120 is, for example, 40% or higher, preferably 60% or higher.

As described above, the light emitting element 1 when observed from the first face 11A side has a large difference in brightness between the light emitting element 1 and the area in the vicinity of the light emitting element 1. Thus, in the case of individually ON-OFF controlling the light emitting elements 1 of the light emitting device 100, the chance of allowing the light emitted by a light emitting element 1 to become incident on the wavelength conversion member 120 on an adjacent unlit light emitting element 1 and causing the phosphor contained in the wavelength conversion member 120 on the unlit light emitting element 1 to emit light can be reduced. This can produce a light emitting device 100 having a large difference in brightness between the wavelength conversion member 120 on a lit light emitting element 1 and the wavelength conversion member 120 on an unlit light emitting element 1 when observing the light emitting device 100 from the wavelength conversion member 120 side.

The light emitting device 100 may further include a sealing member 130 disposed on the wiring substrate 101 between the light emitting elements 1. The sealing member 130 is also disposed between the light emitting elements 1 and the upper face of the wiring substrate 101. The sealing member 130 reflects the light emitted by an active layer 12 and the wavelength conversion member 120, for example. The reflectance of the sealing member 130 for the peak wavelength of the light emitted by an active layer 12 is, for example 60% or higher, preferably 80% or higher. The reflectance of the sealing member 130 for the peak wavelength of the light emitted by the wavelength conversion member 120 is, for example 60% or higher, preferably 80% or higher. The wavelength conversion member 120 is also disposed on the upper face of the sealing member 130 located between adjacent light emitting elements 1. The sealing member 130 includes, for example, a base material and a light diffusing material that can diffuse the light emitted by an active layer 12 and the wavelength conversion member 120. For the base material for the sealing member 130, for example, a silicone resin, epoxy resin, or acrylic resin can be used. For the light diffusion material for the sealing member 130, for example, particles of TiO₂, SiO₂, Al₂O₃, ZnO, MgO, ZrO₂, Y₂O₃, CaF₂, MgF₂, Nb₂O₅, BaTiO₃, Ta₂O₅, BaSO₄, or glass can be used.

Embodiments of the present invention can include the light emitting elements described below.

In the foregoing, certain embodiments of the present invention have been described with reference to specific examples. The present invention, however, is not limited to these specific examples. All forms implementable by a person skilled in the art by suitably making design changes based on any of the embodiments of the present invention described above also fall within the scope of the present invention so long as they encompass the subject matter of the present invention. Furthermore, various modifications and alterations within the spirit of the present invention that could have been made by a person skilled in the art also fall within the scope of the present invention.

1. A light emitting element comprising:
a semiconductor structure comprising:
a first semiconductor layer that has:
a first face that has a peripheral region, and a central region surrounded by the peripheral region in a plan view, wherein a surface roughness of the central region is higher than a surface roughness of the peripheral region, and
a second face that opposes the first face and has a first region and a second region,
an active layer disposed on the first region, and
a second semiconductor layer disposed on the active layer;
a first electrode disposed on the second region and electrically connected to the first semiconductor layer;
a second electrode disposed on the second semiconductor layer and electrically connected to the second semiconductor layer;
a first reflecting film disposed only on the peripheral region of the first face among the surfaces of the semiconductor structure; and
a first protective film disposed on the central region, wherein a light transmittance of the first protective film for a peak wavelength of the light emitted by the active layer is higher than a light transmittance of the first reflecting film for the peak wavelength of the light emitted by the active layer.

2. The light emitting element according to claim 1, wherein the first reflecting film has a first portion that overlaps the peripheral region in a plan view, and a second portion that extends from the first portion outward from the semiconductor structure in the plan view.

3. The light emitting element according to claim 2, wherein an area of the second portion is smaller than an area of the first portion in a plan view.

4. The light emitting element according to claim 1, further comprising:
a second protective film disposed on the lateral faces of the semiconductor structure that connect the first face and the upper face of the second semiconductor layer; wherein:
in a plan view, a perimeter of the second protective film coincides with or is positioned inward of a perimeter of the first reflecting film.

5. The light emitting element according to claim 2, further comprising:
a second protective film disposed on the lateral faces of the semiconductor structure that connect the first face and the upper face of the second semiconductor layer; wherein:
in a plan view, a perimeter of the second protective film coincides with or is positioned inward of a perimeter of the first reflecting film.

6. The light emitting element according to claim 3, further comprising:
a second protective film disposed on the lateral faces of the semiconductor structure that connect the first face and the upper face of the second semiconductor layer; wherein:
in a plan view, a perimeter of the second protective film coincides with or is positioned inward of a perimeter of the first reflecting film.

7. The light emitting element according to claim 1, wherein:
the first reflecting film comprises a first dielectric multilayer film comprising a plurality of first films and a plurality of second films.

8. The light emitting element according to claim 2, wherein:
the first reflecting film comprises a first dielectric multilayer film comprising a plurality of first films and a plurality of second films.

9. The light emitting element according to claim 3, wherein:
the first reflecting film comprises a first dielectric multilayer film comprising a plurality of first films and a plurality of second films.

10. The light emitting element according to claim 7, further comprising:
a second reflecting film that covers the second semiconductor layer; wherein:
the second reflecting film comprises a second dielectric multilayer film comprising a plurality of third films and a plurality of fourth films;
a thickness of each of the first films is larger than a thickness of each of the third films; and
a thickness of each of the second films is larger than a thickness of each of the fourth films.

11. The light emitting element according to claim 8 further comprising:
a second reflecting film that covers the second semiconductor layer; wherein:
the second reflecting film comprises a second dielectric multilayer film comprising a plurality of third films and a plurality of fourth films;
a thickness of each of the first films is larger than a thickness of each of the third films; and
a thickness of each of the second films is larger than a thickness of each of the fourth films.

12. The light emitting element according to claim 9 further comprising:
a second reflecting film that covers the second semiconductor layer; wherein:
the second reflecting film comprises a second dielectric multilayer film comprising a plurality of third films and a plurality of fourth films;
a thickness of each of the first films is larger than a thickness of each of the third films; and
a thickness of each of the second films is larger than a thickness of each of the fourth films.

13. The light emitting element according to claim 1, wherein:
the first protective film is continuously disposed on the central region and the first reflecting film on the peripheral region; and
a surface of the first protective film on the central region is rougher than a surface of the first protective film on the first reflecting film.

14. The light emitting element according to claim 2, wherein:
the first protective film is continuously disposed on the central region and the first reflecting film on the peripheral region; and
a surface of the first protective film on the central region is rougher than a surface of the first protective film on the first reflecting film.

15. The light emitting element according to claim 3, wherein:
the first protective film is continuously disposed on the central region and the first reflecting film on the peripheral region; and
a surface of the first protective film on the central region is rougher than a surface of the first protective film on the first reflecting film.

16. The light emitting element according to claim 1 further comprising:
a second reflecting film that covers the second semiconductor layer and overlaps the first reflecting film in a plan view; wherein:
an overlapping area of the first reflecting film and the second reflecting film is 40% of the area of the first reflecting film or larger.

17. The light emitting element according to claim 2 further comprising:
a second reflecting film that covers the second semiconductor layer and overlaps the first reflecting film in a plan view; wherein:
an overlapping area of the first reflecting film and the second reflecting film is 40% of the area of the first reflecting film or larger.

18. The light emitting element according to claim 3 further comprising:
a second reflecting film that covers the second semiconductor layer and overlaps the first reflecting film in a plan view; wherein:
an overlapping area of the first reflecting film and the second reflecting film is 40% of the area of the first reflecting film or larger.
